(19) United States
(12) Patent Application Publication
(10) Pub. No.: US 2026/0055778 A1
(43) Pub. Date: Feb. 26, 2026

(54) HOT-SWAP EASY-ACCESS FAN ENCLOSURE

(71) Applicant: Zoho Corporation Private Limited, Kanchipuram District (IN)

(72) Inventors: Adarsh Ashok Mishra, Chitrakoot (IN); Yash Manoj Kadu, Nagpur (IN); Devesh Laxmichand Khadgi, Nagpur (IN); Rushikesh Vijayrao Pawade, Nagpur (IN)

(73) Assignee: Zoho Corporation Private Limited, Kanchipuram District (IN)

(21) Appl. No.: 19/273,032

(22) Filed: Jul. 17, 2025

Related U.S. Application Data
(60) Provisional application No. 63/704,033, filed on Oct. 7, 2024.

(30) Foreign Application Priority Data
Aug. 21, 2024 (IN) 202441063244

(51) Int. Cl. F04D 29/52; F04D 19/00; F04D 29/02; F04D 29/64; H05K 7/20

(52) U.S. Cl. CPC F04D 29/522; F04D 19/002; F04D 29/023; F04D 29/646; H05K 7/20172

(57) ABSTRACT

A server drawer is configured to house arrays of fans. A row of fan enclosures can be inserted into a fan cage which is affixed to the server drawer. The tray is fastened to the server drawer with fasteners. Alternately, the tray is configured with fan cage locking handles, operable with a fan cage mount affixed to sidewalls of the server drawer. The fan cage is hot-swappable by grasping the handles and compressing them to release latches. The fan enclosures are placed in the fan cage with no need for attachment mechanisms. Detents provide tension between fan enclosures to maintain their placement and provide vibration isolation. Fan connectors are mounted such that each is aligned with and connects with a fan control/power connector on a printed circuit board (PCB) mounted below. Handles allow the fan enclosure to be grasped and removed with no tools or fasteners required. The fan enclosure is a unitary body, with extruded mounts, designed to accept a fan into an opening securing onto the mounts with no need for fasteners. The fan enclosure and cage are designed to cost-effectively allow hot swapping without tools.

### CROSS REFERENCE TO RELATED APPLICATIONS

This application is related to Indian Provisional Application 202441063244, filed 21 Aug. 2024, and U.S. Provisional Application 63/704,033 filed 7 Oct. 2024, both entitled “HOT-SWAP EASY-ACCESS FAN ENCLOSURE”, both of which are incorporated herein by reference.

### FIELD OF THE INVENTION

Embodiments of the present disclosure are related, in general, to data servers and more particularly, but not exclusively, to server fan enclosures.

### BRIEF DESCRIPTION OF THE DRAWINGS

The subject matter disclosed is illustrated by way of example, and not by way of limitation, in the figures of the accompanying drawings and in which like reference numerals refer to similar elements and in which:

FIGS. 1A-1C depict three views of a fan enclosure 100. FIG. 1A shows the front and left sides, FIG. 1B shows the back and left sides, and FIG. 1C shows the front view.

FIG. 2A depicts the back and right sides of fan enclosure 100 as well as a fan 200. FIGS. 2B-2D illustrate the insertion of fan 200 into fan enclosure 100.

FIGS. 3A-3C illustrate the insertion of fan connector 220 into connector bracket 130.

FIGS. 4A-4C illustrate an enclosed fan assembly 300 being inserted into a fan cage 400 alongside other fan assemblies 300.

FIGS. 5A-5C illustrate a populated fan cage 400 being inserted into a server drawer 600.

FIGS. 6A-6C show additional views of fan cage 400 installed in server drawer 600.

FIG. 7A shows a locking handle 410. FIG. 7B shows a mounting bracket 510. FIG. 7C shows a fan cage 400 with a locking handle 410 attached, being inserted into a mounting bracket 510.

FIG. 8A shows a sketch view of the example 1 fan enclosure, with fan and connector (2U, 60×60×38). FIG. 8B shows an isometric view.

FIGS. 9A-9F show the front, back, left, right, top, and bottom views of the example 1 fan enclosure.

FIGS. 10A-C show the isometric, top, and front views of the server drawer assembly for example 2 (3U or 4U, 80×80×38).

FIG. 11A shows a sketch view of the example 2 fan enclosure, with fan and connector. FIG. 11B shows an isometric view.

FIGS. 12A-12F show the front, back, left, right, top, and bottom views of the example 2 fan enclosure.

### DETAILED DESCRIPTION

A server drawer is configured to house arrays of fans, in a row of fan enclosures inserted into a fan cage, affixed to the server drawer. The tray is fastened to the server drawer with fasteners. Alternately, the tray is configured with fan cage locking handles, operable with a fan cage mount affixed to sidewalls of the server drawer. In this embodiment, the fan cage is hot-swappable by grasping the handles and compressing them to release latches.

The fan enclosures are placed in the fan cage with no need for attachment mechanisms. Detents provide tension between fan enclosures to maintain their placement and provide vibration isolation. Fan enclosures are housed within a fan cage such that, when the fan cage is attached or inserted into a server drawer, a fan connector on each fan enclosure is aligned with and connects with a fan control/power connector on a printed circuit board (PCB) mounted below.

Handles allow the fan enclosure to be grasped and removed from a fan cage with no tools or fasteners required. The fan enclosure is a unitary body, with extruded mounts, designed to accept a fan into an opening securing onto the mounts. Again, there is no need for fasteners. The fan enclosure and cage are designed to cost-effectively allow hot swapping of fans without tools. In the alternate embodiment introduced above, the entire fan cage is hot swappable without tools.

A server is a powerful computer designed to process, manage, and deliver data to other computers over a network. Typically housed in a data center, servers come in various configurations, often stacked in racks that provide a standardized structure for mounting multiple servers and related equipment. These racks are equipped with drawers, or “rack units” (RUs), which are standardized in height and allow for efficient use of space. Each unit is 1.75 inches in height, with common server sizes ranging from 1U to 4U. A 1U server is the thinnest and most compact, while a 4U server is larger and can accommodate more components and powerful cooling systems.

Air circulation is a critical aspect of server operation. Servers generate significant heat due to their powerful components and high workloads. To prevent overheating and ensure reliable performance, servers are equipped with advanced cooling systems. These include internal fans that draw cool air in and expel hot air out, as well as heat sinks that dissipate heat from key components like the CPU and GPUs. Additionally, data centers use sophisticated climate control systems to maintain optimal temperature and humidity levels. Efficient air circulation and cooling help prevent hardware failures and prolong the lifespan of server components.

The standard sizes for server drawers, from 1U to 4U, cater to different needs and capacities. A 1U server, being the most compact, is ideal for environments where space is at a premium and efficiency is crucial. These servers are often used for web hosting, small-scale applications, and services that require less computational power. On the other hand, 2U, 3U, and 4U servers offer increased space for additional components, better cooling solutions, and more storage options. They are suited for more demanding applications, such as database management, virtualization, and large-scale computing tasks. The choice of server size depends on the specific requirements of the organization, balancing the need for performance, space efficiency, and scalability.

Hot swapping is a critical feature in server maintenance that allows for the replacement or addition of components such as hard drives, power supplies, and fans without shutting down the system. This capability is essential for maintaining the continuous operation of servers, which is crucial in environments where downtime can lead to significant disruptions and financial losses. Hot-swappable components are designed to be easily accessible, typically mounted in a way that they can be quickly removed and replaced, ensuring minimal interruption to server operations. For instance, if a fan fails, it can be swiftly replaced to maintain proper cooling and prevent overheating, which could damage other components. This approach to maintenance ensures high availability and reliability of the server infrastructure, enabling IT staff to address issues promptly without affecting the overall performance and service delivery.

A server drawer can be configured to house arrays of fans. In the example embodiment, a row of fans is deployed in a tray, spanning the width of the server drawer. The number of fans in the row is a function of factors such as the width of the drawer, the height of the drawer (e.g. 1U-4U), and the size of the fans. A variety of standardized fans of differing form factors are readily available on the market. Fan enclosures support several aspects for housing fans. A row of fan enclosures can be inserted into a tray, also called a fan cage. The fan cage is affixed to the server drawer.

In one embodiment, the tray is fastened to the server drawer with fasteners. In an alternate embodiment, the tray is configured with fan cage locking handles, operable with a fan cage mount affixed to sidewalls of the server drawer. The entire fan cage is hot-swappable by grasping the handles, compressing them to release latches, and pulling the fan cage from the mount.

The fan enclosures are simply placed into the fan cage, side by side, with no need for clips or other attachment mechanisms. Detents on the side of the fan enclosures provide tension between them to maintain their placement securely and to protect against undue wear and tear by providing vibration isolation. Fan connectors are mounted to the fan enclosure such that when the enclosure is inserted into the fan cage (or if an entire row of enclosures are inserted along with the fan cage) each fan connector is aligned with and connects with a fan control/power connector on a printed circuit board (PCB) mounted below the fan cage (e.g. attached to the bottom of the server drawer with appropriate standoffs to maintain the required clearance. A set of lifting handles is provided on top of each enclosure to allow it to be securely grasped and removed simply and speedily, with no tools or fasteners required.

The fan enclosure is formed as a unitary body, including extruded mounts, the body designed with mount placement to accept a fan into an opening and receive the fan holes onto the mounts, thus securing the fan quickly and with no need for fasteners. The fan connector is inserted into a connector bracket. When hot-swapping, the reverse process allows the fan to be removed and replaced easily. The fan is simply pulled away from the mounts until disengaged and the fan is removed from the housing. The fan connecter slides out of the connector bracket. Then a new fan is inserted, and the enclosure is placed back in the fan cage, where the connector will engage with the PCB and the fan begins operation once more.

Fan enclosures can be manufactured inexpensively, e.g. injection-molded plastic. Contrast this with prior art fan enclosures which may include multiple pieces, may require tools or screws, may require manual connection of fan connectors, and the like, all of which can increase cost as well as time required to swap a new fan for a used one. Alternate materials may be substituted, including metal or composite materials.

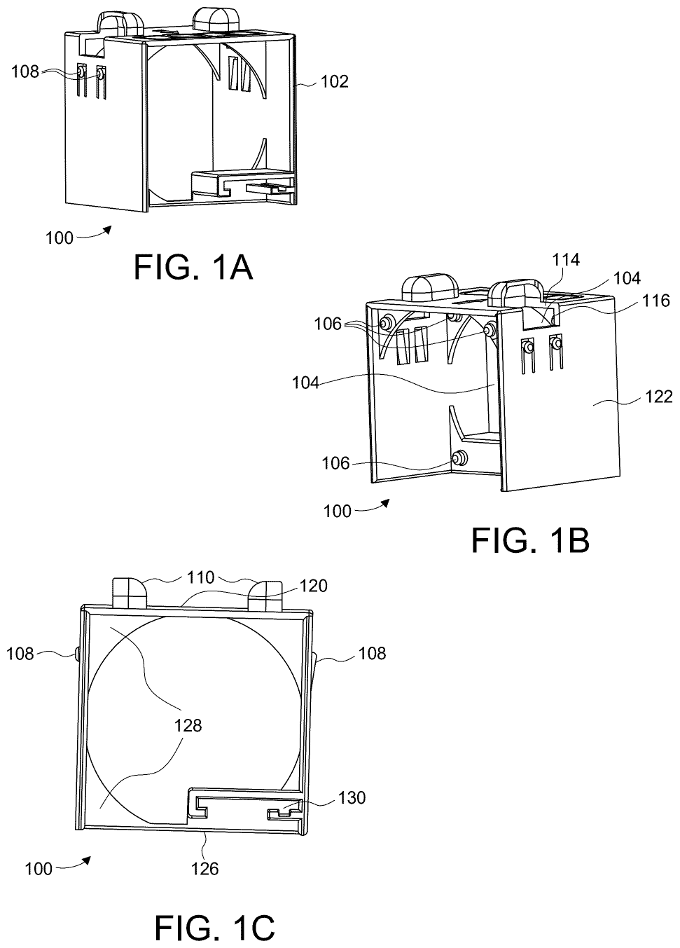

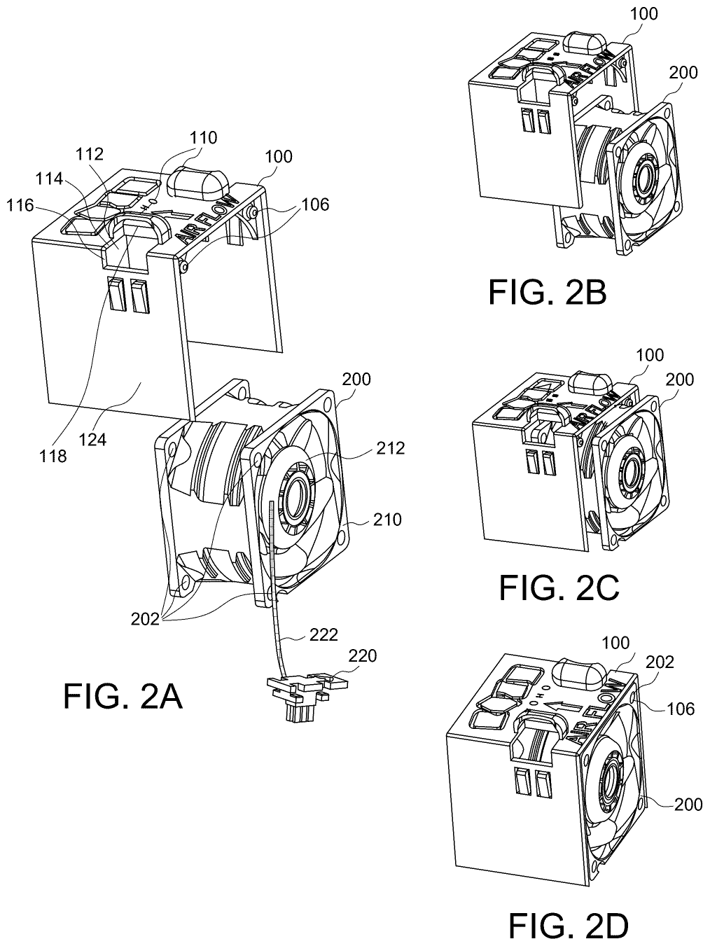

FIGS. 1A-1C depict three views of a fan enclosure 100. FIG. 1A shows the front and left sides, FIG. 1B shows the back and left sides, and FIG. 1C shows the front view. FIG. 2A depicts the back and right sides of fan enclosure 100 as well as a fan 200. FIGS. 2B-2D illustrate the insertion of fan 200 into fan enclosure 100. Fan enclosure 100 is hollow and has an opening 104 framed by the top 120, left side 122, right side 124, and bottom 126, as well as supports 128. Fan mounts 106 extrude from supports 128. There are 4 supports 128 near the front and two supports 128 near the rear, on top. In an alternate embodiment, an additional two supports 128 with mounts 106 could be included in the back bottom.

The enclosure (100) comprises a unitary body (102) forming a hollow interior and an opening (104), configured to receive a fan (such as fan 200 detailed below). The body is integrally formed as a single piece with the opening having a shape and size adapted to accommodate the fan. The body further comprises one or more mounting features 106 adjacent to the opening for securing the fan 200 in place. In one embodiment, the mounting feature 106 is a circular extruded feature, sized in accordance with the diameter of and for inserting into a mounting hole (202) in the fan. The interior of the body is designed to facilitate airflow from the fan through the enclosure.

The enclosure comprises one or more detents (108), or vibration isolators, which retract and apply pressure to an adjacent enclosure or other structure to secure the unitary enclosure in place and to provide vibration isolation from an enclosed fan during operation. Two lifting handles (110) facilitate easy grasping with two fingers, each handle integrally formed with the body, having a convex side raised from the top (120) of the body, adjacent to a handle aperture (112) formed in the body, the handle aperture formed by a cutout (114) of the top of the body, and optionally a cutout (116) on a side of the body (122) adjacent to the cutout on the top of the body. The enclosure comprises a connector bracket (130) for receiving a fan connector (e.g. 220).

As shown in FIGS. 2B-2D, the fan 200 is placed into the opening 104. Fan 200 has a frame or housing 210 which surrounds and supports a motor assembly 212 comprising fan blades and control circuitry, which is controlled and powered through wire 222 via connector 220. Fan 200 has 8 holes 202 in frame 210, four in the front and 4 in the back. The fan is placed into opening 104 such that the front four holes 202 move beyond the back supports 128 (FIG. 2B). Then the fan can be moved toward the top of the enclosure 100 (FIG. 2C). Then the fan can be pressed forward where the fan holes 202 will engage with and connect to mounts 106, and the fan is now positioned and secure in the enclosure (FIG. 2D).

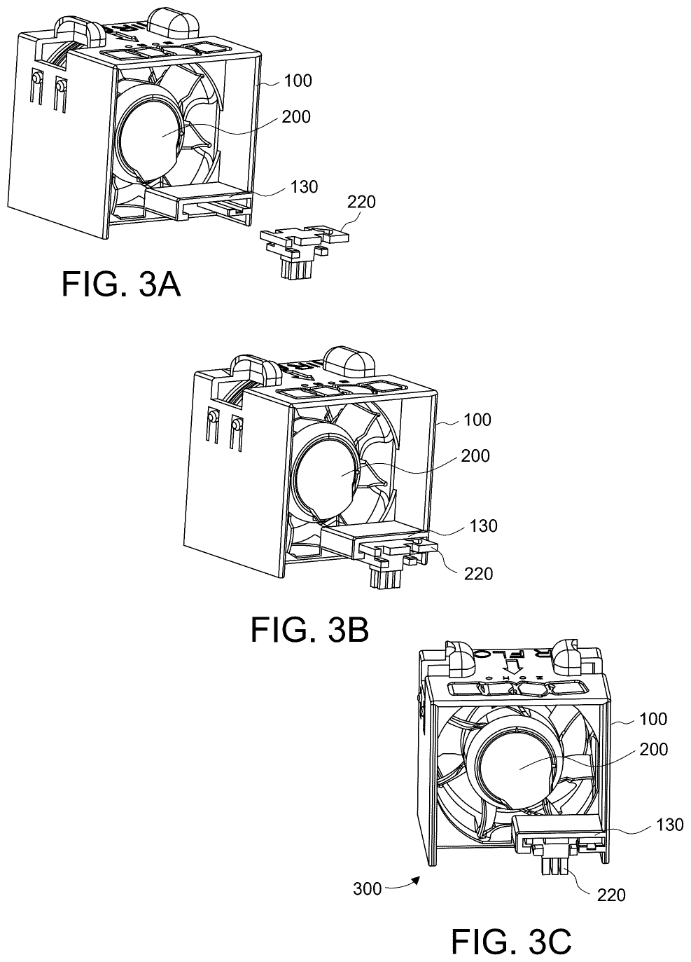

FIGS. 3A-3C illustrate the insertion of fan connector 220 into connector bracket 130. There will typically be wired connections from the fan connector 220 to the fan 200 to provide power and control (details omitted). Connector bracket 130 is designed to receive connector 220 as shown in FIG. 3A. The connector is partially inserted in FIG. 3B. Enclosed fan assembly 300 with the fan connector 220 in place is shown in FIG. 3C, and the location of the connector in the bracket is designed to connect with a mate on a PCB (detailed further below).

In an alternate embodiment, a fan can be manufactured with the features of enclosure 100 integrated into a fan housing 210, creating a unitary fan/enclosure. The fan connector can be fixed in the appropriate position of such an enhanced fan frame, or a connector bracket 130 as described above can be deployed.

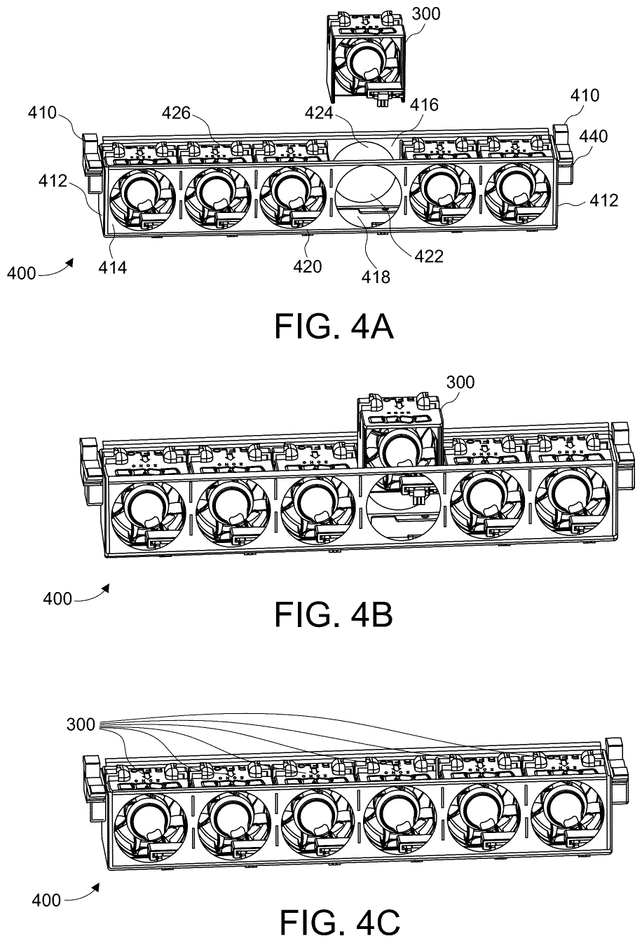

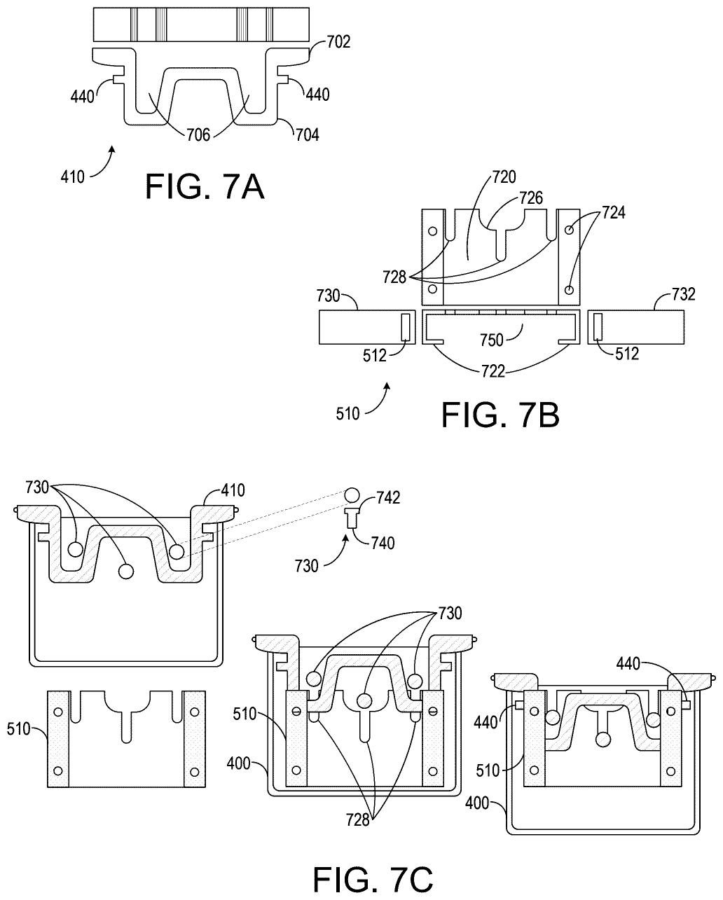

FIGS. 4A-4C illustrate an enclosed fan assembly 300 being inserted into a fan cage 400 alongside other fan assemblies 300. Fan cage 400 forms a tray for housing the fan assemblies comprising two end sides 412, a front side 414, a back side 416, and a bottom 418. The top is open to receive fan assemblies 300, as illustrated. There is a back aperture 424 and a front aperture 422 positioned to allow air flow freely from back to front for each installed fan assembly 300. The bottom 418 has an aperture 420 positioned to allow connection to connector 220 of each installed fan assembly 300. Each end side 412 has a locking handle 410 attached, the handle comprising a latch 440 (detailed below in FIG. 7). An assembly 300 is simply inserted into vacant space through the top 426 as shown. FIG. 4B shows assembly 300 partially inserted, and the completely populated fan cage 400 is illustrated in FIG. 4C. No clips, fasteners, or other attachment devices are required. The fan assemblies reside side by side, contacting each other via detents 108.

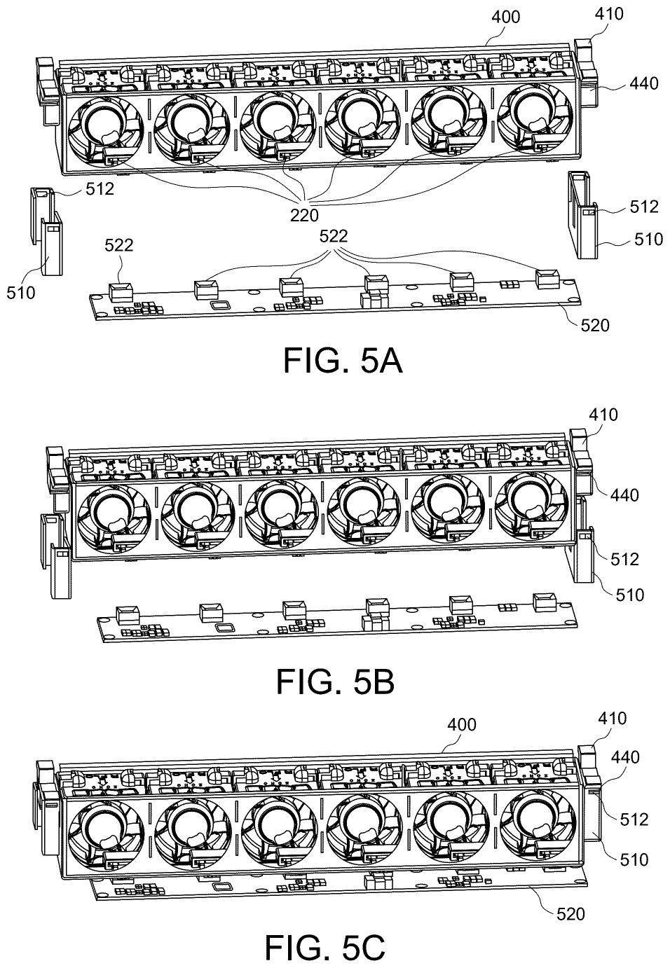

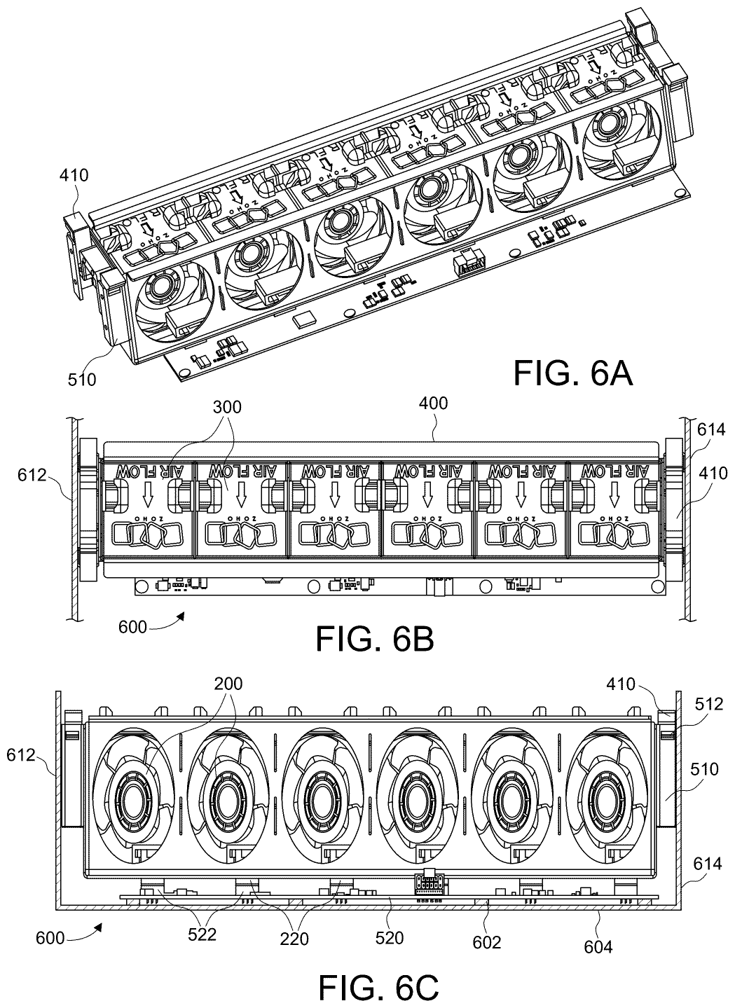

FIGS. 5A-5C illustrate a populated fan cage 400 being inserted into a server drawer 600. Mounting brackets 510 are affixed to sidewalls of the server drawer (detailed in FIG. 6C). The locking handles 410 and fan cage mounting posts guide and slide into mounting brackets 510, each bracket having a catch 512 (detailed in FIG. 7), above printed circuit board (PCB) 520, such that, when fully inserted, the fan connectors 220 align and couple with respective PCB fan control connectors 522. The partially inserted fan cage 400 is illustrated in FIG. 5B and in its final position in FIG. 5C. It can be seen that the latch 440 on each side of a locking handle 410 is seated into a corresponding catch 512, and so the fan cage 400 is locked into the mounting brackets 510.

FIGS. 6A-6C show additional views of fan cage 400 installed in server drawer 600. FIG. 6A shows an alternate isometric view of the installed populated fan cage 400. Additional detail of the locking handle 410 as inserted in mounting bracket 510 can be seen. FIG. 6B shows the top view of the fan cage 400 inserted into two mounting brackets 510, each of which are attached to sidewalls 612 and 614 of the server drawer 600. FIG. 6C shows a cutout front view showing the same, as well as PCB board 520, connected to the fans through PCB fan control connectors 520 and fan connectors 220. The PCB board 520 is mounted to the bottom 604 of the server drawer 600 using offsets 602 to keep clearance as required between the drawer and the board, and to position the board such that the fan enclosure assemblies 300 will align and connect (220 to 522) when a loaded fan cage 400 is inserted into the server drawer 600, or when a fan enclosure assembly 300 is loaded into an already inserted fan cage 400.

FIG. 7A shows a locking handle 410. A top view and front view are shown. The handle comprises two u-shaped bends 706, and two sides each with a grip 702 and latch 440 attached to an arm 704. The u-shaped bends act as a spring, allowing the arms 704 to retract when opposing pressure is applied to each grip 702, which moves the respective latches 104 inward. When the pressure is removed, the arms 704 return to their original position.

FIG. 7B shows a mounting bracket 510. In the example embodiment the bracket is formed by folding sheet metal to produce two sides, 730 and 732, a front face 720, and two back flaps 722. Channel 750 is formed by the 3 sides and back flaps, into which locking handle 410 may be inserted. The figure shows a top view of the bracket, with side views to the right and left, and a rear view above. The two back flaps 722 have two holes 724 for attaching the mounting bracket 510 to a server wall (612 or 614). Rivets are used in the example embodiment; alternates may be substituted. Right side 730 and left side 732 each have a catch 512, which can receive a latch 440. Front face 720 has slots 728 cut out of the face which are designed in positions to receive mounting posts attached to a fan cage. A cutout notch 726 directs a mounting post toward the center slot 728 as that post is moved downward from the top. Alternate materials and manufacturing techniques may be used to form a mounting bracket 510.

FIG. 7C shows a fan cage 400, with a locking handle 410 attached, being inserted into a mounting bracket 510. An end view of fan cage 400 shows mounting handle 410 attached to one side of the cage. Additionally, three mounting posts 730 are shown attached to the end of fan cage 400. The opposite side is configured similarly. In one embodiment, a mounting post 730 comprises a post 740 with a head 742. Alternate numbers and styles of posts (e.g. no head) may be substituted. Below fan cage 400 is an empty mounting bracket 510 ready to receive the fan cage 400. To the right, the fan cage 400 is shown partially inserted into the bracket 510. It can be seen that the mounting posts 730 are heading toward the slots 728, and cutout notch 726 would redirect the cage if the respective mounting post is to the right or left of the center slot 728. As the cage continues down, the locking handle slides further into channel 750. The latches 440 on each of the locking handles 410 will eventually contact the top of sides 730 and 732. In the figure, the latches will stop on the top, unless force is applied to the grips to move the arms 704 inward, which clears the latches and allows the cage to continue. When the cage is fully inserted, the latches 440 will seat in the catches 512, as shown on the right figure. In an alternate embodiment, an angled latch 440 will automatically retract the arms to allow the cage to proceed. Removal is straightforward: reapply force to the grips, easily done with two fingers, to release the latch and pull the handles up to remove the cage. Each individual fan assembly 300 is hot-swappable, as is the entire fan cage.

In alternate embodiments, a single catch and a single corresponding latch may be deployed. In alternate embodiments a single u-shape bend may be deployed, with a single arm or both arms attached and moveable in response. In yet another embodiment, no catch or latch are deployed, and the arms 704 may contact the sides of mounting bracket 510, the u-shape bend or bends 706 acting as a compressed spring and applying pressure to the wall to keep the fan cage seated.

Various embodiments can be designed using components of any size, including any size server drawer supporting any size of fan cage (including a narrower version utilizing adapter hardware if desired. The number of fans deployed within a fan cage is a function of the fan cage size, the size of the fans, and the size of the fan enclosures. With custom manufacturing, there are myriad embodiment variations. Nonetheless, it may be desirable to utilize standard components and adapt to standardized design parameters in certain embodiments. Two of them are detailed herein as illustrations. The embodiment detailed above in FIGS. 1-7 is a first example. It is designed to accommodate 6 fans of size 60 mm×60 mm×38 mm in hot-swapping enclosures as described, populating a hot-swappable fan cage with locking handles within a 2U server drawer. A second example will be detailed further below. It is designed to accommodate 5 larger fans of size 80 mm×80 mm×38 mm in hot-swapping enclosures as described, populating a fixed fan cage within a 3U or 4U server drawer. This second example illustrates a fixed fan cage rather than a hot-swappable cage, a design choice made due to size limitations of the drawer based on the chosen fan width.

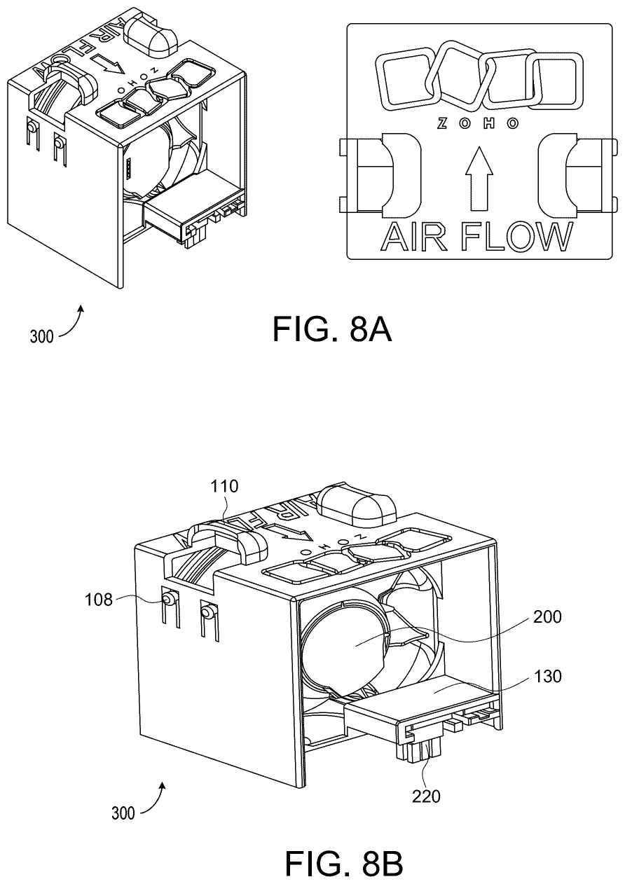

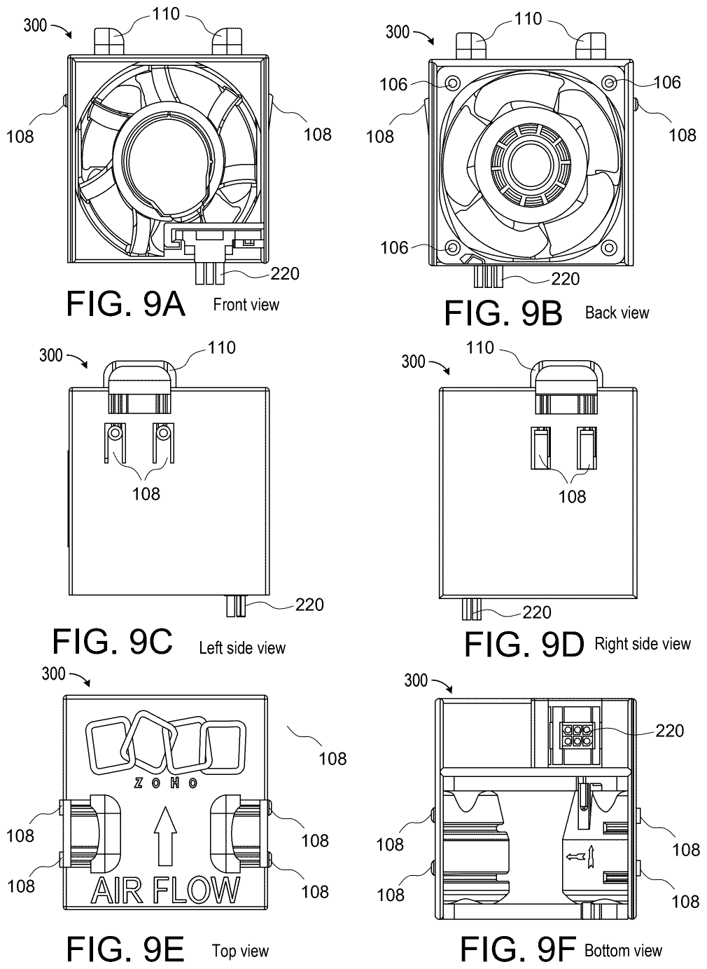

The server drawer assembly for example 1 (2U, 60×60×38), including fan cage, mounting brackets, and fan enclosures are detailed above throughout FIGS. 1-7, and specifically in FIG. 6. Additional views of the fan enclosure assembly 300 for example 1 are detailed in FIGS. 8-9. FIG. 8A shows a sketch view of the example 1 fan enclosure, with fan and connector. FIG. 8B shows an isometric view. FIGS. 9A-9F show the front, back, left, right, top, and bottom views.

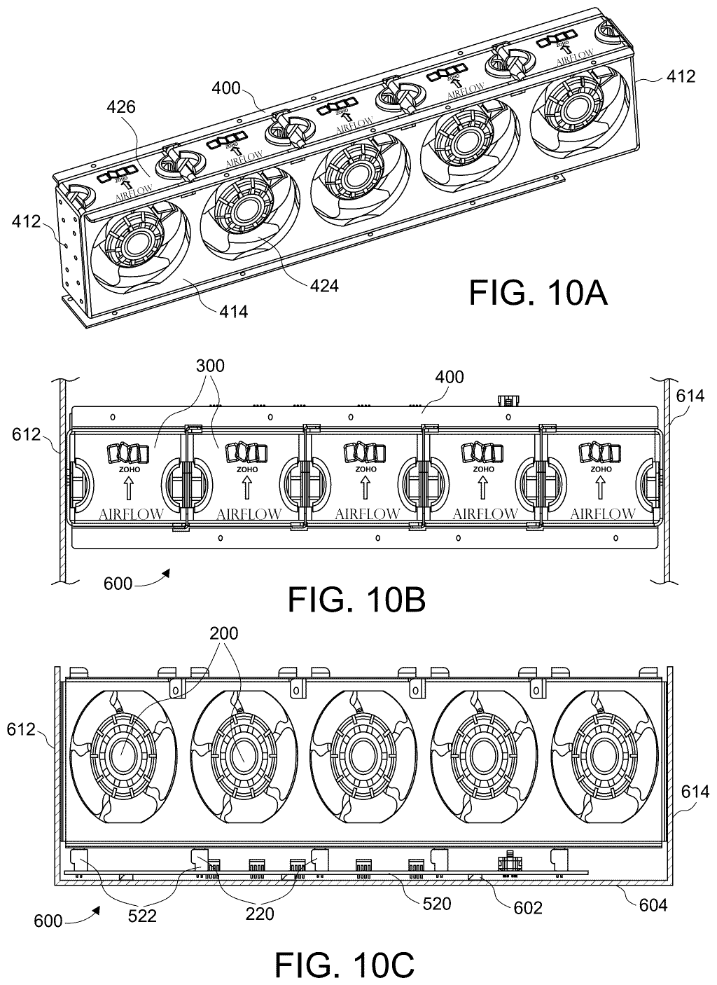

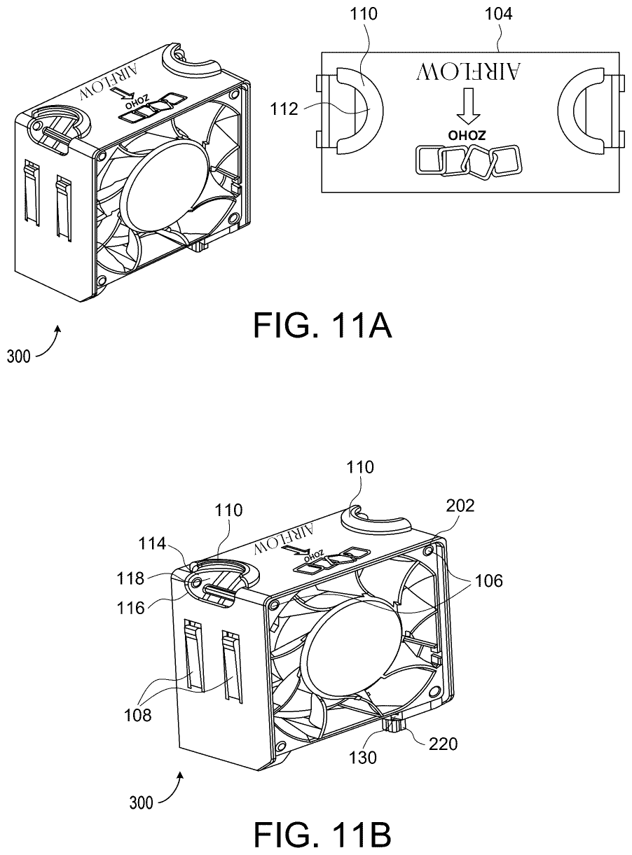

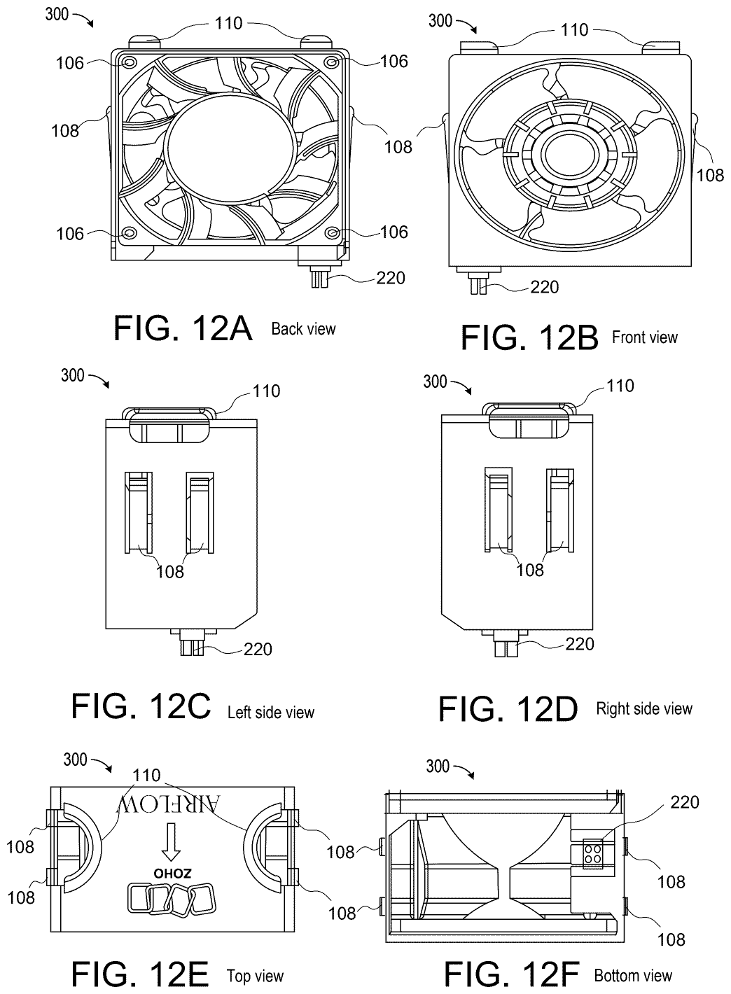

FIGS. 10A-C show the isometric, top, and front views of the server drawer assembly for example 2 (3U or 4U, 80×80×38). Additional views of the fan enclosure assembly 300 for example 2 are detailed FIGS. 11-12. FIG. 11A shows a sketch view of the example 2 fan enclosure, with fan and connector. FIG. 11B shows an isometric view. FIGS. 12A-12F show the front, back, left, right, top, and bottom views. Numbering of features in example 2 match like features in example 1, detailed above. In this example, a locking handle and mounting bracket are not utilized. Instead, the fan cage is mounted to the sidewalls of the server drawer.

Note that vibration isolators 108 are aligned right and left among neighboring fan enclosures in the fan cage. In one embodiment, the space is not sufficient to accommodate vibration isolators with the same design on the left and right (e.g. FIGS. 9A-F). When the fan enclosure is mounted in the fan cage, the left vibration isolators are slightly protruded out of the fan enclosure, whereas the right vibration isolators are more closely aligned with the wall of the fan enclosure. Hence, less space is needed for the right vibration isolators than the left vibration isolators. In another embodiment, the isolators can be the same (e.g. FIGS. 12A-F).

Several benefits of the embodiments detailed above are summarized as follows. The fan enclosure facilitates reduced time-consuming maintenance. The easy installation and removal of the fan significantly reduces the time needed to access and service each fan and its connector. Mounting of each fan securely in place is crucial to prevent operational issues. Circular extruded parts for the fan holding mechanism provide a stable and secure mounting for the fan. Fan enclosures are easily removed from a fan cage with two fingers via opposing handles. The latch handle mechanism in the fan cage embodiment of example 1 allows for easy unlocking and lifting of the fan cage, improving accessibility.

During operation, fans generate vibration that can cause noise, wear & tear on the fan and surrounding components. By including vibration isolators, vibrations are minimized leading to smoother operation. The screwless design for the fan assembly, allows quick and easy installation and removal. This eliminates the need for tools and reduces maintenance time when swapping a fan. Elegant design, minimizing components, and utilizing unitary parts which can be manufactured inexpensively lowers cost relative to existing solutions.

The fan enclosure is a protective housing that surrounds and secures a fan unit. It shields the fan, also providing safety for users. In the example embodiment, made of plastic, it is designed to maximize airflow while minimizing noise. Components such as a fan mounting, connector bracket, and vibration isolators are incorporated to ensure efficient and reliable fan operation. The fan enclosure features circular extrusions for holding the fan and attaching the connector bracket, ensuring secure positioning. When inserted into a fan cage, the enclosure automatically locks into place, eliminating the need for additional fasteners and ensuring stability.

The connector bracket in the fan enclosure is designed to hold the connector of the fan securely. Its purpose is to facilitate easy removal and reinsertion of the connector, making maintenance and operation more convenient. It ensures that connection can be quickly and safely established. There is a space constraint in example 1, so an option is illustrated where the fan connector is provided in the front of the enclosure. An alternate where there is no such constraint is illustrated in the example 2, where the connector is placed below the enclosure.

Six circular extruded parts serve as fan mountings to hold the fan firmly in place. Other configurations with fewer or more mountings may be deployed. These parts are strategically positioned within the enclosure to ensure proper alignment and stability of the fan. The lifting handle is designed for easy lifting and removal of fan enclosure. This handle allows the user to safely and efficiently lift the enclosure away from the fan cage. Its design ensures a secure grip, making it easier to handle the enclosure during maintenance or inspection.

The foregoing description of the implementations of the present techniques and technologies has been presented for the purposes of illustration and description. This description is not intended to be exhaustive or to limit the present techniques and technologies to the precise form disclosed. Many modifications and variations are possible in light of the above teaching. It is intended that the scope of the present techniques and technologies are not limited by this detailed description. The present techniques and technologies may be embodied in other specific forms without departing from the spirit or essential characteristics thereof. Accordingly, the disclosure of the present techniques and technologies is intended to be illustrative and not limiting. Therefore, the spirit and scope of the appended claims should not be limited to the foregoing description. In U.S. applications, only those claims specifically reciting “means for” or “step for” should be construed in the manner required under 35 U.S.C. § 112(f).

What is claimed is:

1. An enclosure, operable with a fan, the enclosure comprising:
a unitary body forming a hollow interior and an opening, the opening configured to receive the fan and designed to facilitate airflow from the fan through the enclosure;
wherein:
the body is integrally formed as a single piece;
the opening has a shape and size adapted to accommodate the fan; and
the body further comprises at least one mounting feature adjacent to the opening for securing the fan in place.

2. The enclosure of claim 1, wherein the body is constructed from a material selected from the group consisting of plastic, metal, composite materials, or combinations thereof.

3. The enclosure of claim 1, wherein the body further comprises:
a first side including one or more exterior detents; and
a second side;
wherein the one or more detents retract and apply pressure to the second side of an adjacent enclosure or other structure to secure the enclosure in place and to provide vibration isolation from an enclosed fan during operation.

4. The enclosure of claim 1, wherein the mounting feature is a circular extruded feature, sized in accordance with the diameter of and for inserting into a mounting hole in the fan.

5. The enclosure of claim 1, wherein the body further comprises a top including two lifting handles, each handle integrally formed within the body, having a convex side raised from the top of the body.

6. The enclosure of claim 5, wherein at least one of the handles is adjacent to a handle aperture formed in the body, the handle aperture formed by a cutout of the top of the body.

7. The enclosure of claim 6, wherein the handle aperture further comprises a cutout on a side of the body, the cutout on the side of the body adjacent to the cutout on the top of the body.

8. The enclosure of claim 1, further comprising a connector bracket for receiving a fan connector.

9. A fan cage comprising:
an open top;
a front wall;
a back wall;
two opposing sidewalls; and
a bottom;
wherein:
the fan cage is configured to receive a plurality of fan enclosures through the open top in a side-by-side arrangement;
the front wall and back wall include apertures aligned with the plurality of fan enclosures to permit airflow therethrough; and
the bottom includes apertures configured to align with fan control connectors on the plurality of fan enclosures for electrical connectivity.

10. The fan cage of claim 9, further comprising a plurality of fan enclosures, each of the plurality of fan enclosures including one or more detents on one or more exterior surfaces, the detents positioned to abut either an adjacent fan enclosure or one of the two sidewalls of the fan cage when inserted, thereby securing the plurality of fan enclosures in the fan cage and providing vibration isolation during operation.

11. The fan cage of claim 10, wherein the plurality of fan enclosures comprise the fan enclosure of claim 1.

12. The fan cage of claim 9 further comprising a locking handle affixed to one or more of the two opposing sidewalls, the locking handle comprising a u-shaped bend including an arm having a latch, the u-shaped bend allowing movement of the arm in response to pressure.

13. A server drawer comprising:
a first side;
a second side; and
an apparatus operable to house a plurality of fans having:
two opposing sides;
a locking handle affixed to one or more of the two opposing sides, the locking handle comprising a u-shaped bend including an arm having a latch, the u-shaped bend allowing movement of the arm in response to pressure; and
a mounting bracket having an opening formed by a plurality of sides, one of the plurality of sides comprising a catch;
wherein:
the mounting bracket is affixed to the first side of the server drawer; and
the locking handle is received into the opening of the mounting bracket such that, when the locking handle is fully inserted, the latch is seated in the catch.

14. The server drawer of claim 13, further comprising:
a printed circuit board comprising a plurality of fan control connectors; and
a bottom onto which the printed circuit board is affixed;
wherein the apparatus includes apertures formed in the apparatus bottom configured to align with the plurality of fan control connectors on the printed circuit board for electrical connectivity with the plurality of fans.

15. The server drawer of claim 13, wherein the apparatus is the fan cage of claim 9.
